(19) United States
(12) Patent Application Publication
(10) Pub. No.: US 2007/0249102 A1
(43) Pub. Date: Oct. 25, 2007

(54) PANEL AND SEMICONDUCTOR DEVICE HAVING A STRUCTURE WITH A LOW-K DIELECTRIC

(75) Inventors: Markus Brunnbauer, Lappersdorf (DE); Edward Fuergut, Dasing (DE); Thorsten Meyer, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Munich (DE)

(21) Appl. No.: 11/738,213

(22) Filed: Apr. 20, 2007

(30) Foreign Application Priority Data
Apr. 21, 2006 (DE) 10 2006 019 244.3

(51) Int. Cl. H01L 21/00; H01L 21/82

(52) U.S. Cl. 438/127; 438/128; 257/678

(57) ABSTRACT

A panel and a semiconductor device, in one embodiment composed of a composite plate with semiconductor chips and plastic housing composition and to a method for producing the same is disclosed. The embodiments include a wiring structure with interconnects and dielectric layers composed of a low-k dielectric is arranged on the top side of the composite plate.

### CROSS-REFERENCE TO RELATED APPLICATIONS

This Utility Patent Application claims priority to German Patent Application No. DE 10 2006 019 244.3 filed on Apr. 21, 2006, which is incorporated herein by reference.

### BACKGROUND

The invention relates to a panel and a semiconductor device, in one embodiment composed of a composite plate with semiconductor chips. The composite plate also has a plastic housing composition in addition to the semiconductor chips. The invention furthermore relates to a method for producing a semiconductor device.

As a result of the increasing miniaturization of semiconductor chips with the ensuing miniaturization of structures such as, for example, interconnects and dielectric layers, parasitic inductive and capacitive disturbances of the lines with respect to one another are increasingly occurring. To reduce these disturbances, layers having the lowest possible relative permittivity are used for insulating the interconnects from one another. SiO₂, which is conventionally used, has a relative permittivity of approximately 4 and the optimum of 1 would correspond to insulation by vacuum. At the present time use is made of various materials having comparatively low relative permittivities, such as, for example, FSG (fluorine-doped SiO₂ having a relative permittivity of between 3.6 and 3.9), SiLK having a relative permittivity of 2.6 or porous SiLK having a relative permittivity of 2.1.

These low-k dielectrics are all porous, however, and therefore very sensitive to mechanical loadings. This is critical particularly when the contact areas of the semiconductor chips lie above the active top side. When testing the semiconductor chips, when making contact with bonding wires or solder balls, or in the case of other, similar loadings, the consequence may therefore be fractures or cracks of the low-k dielectric layer and therefore an undesirably large number of rejects during production.

For these and other reasons there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1-7 illustrate schematic cross sections through fabrication stages of a semiconductor device.

FIG. 1 illustrates a schematic cross section through a carrier with semiconductor chips in semiconductor device positions.

FIG. 2 illustrates a schematic cross section through the carrier in accordance with FIG. 1 after the application of a plastic housing composition and formation of a coplanar top side of a composite plate.

FIG. 3a illustrates a schematic cross section through the self-supporting composite plate after the removal of the carrier from the top side of the composite plate.

FIG. 3b illustrates a plan view of the composite plate in accordance with FIG. 3a.

FIG. 4a illustrates a schematic cross section through the self-supporting composite plate in accordance with FIG. 3 after the application of a wiring structure to the coplanar top side of the composite plate.

FIG. 4b illustrates a plan view of the composite plate in accordance with FIG. 3a.

FIG. 5 illustrates a schematic cross section through the self-supporting composite plate in accordance with FIG. 4 after the application of a soldering resist layer to the coplanar top side of the composite plate.

FIG. 6 illustrates a schematic cross section through a panel after the application of external contacts to the coplanar top side of the composite plate.

FIG. 7 illustrates a schematic cross section through a semiconductor device after the separation of the panel in accordance with FIG. 6 into individual semiconductor devices.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One or more embodiments provide a semiconductor chip and a panel having semiconductor chips having low-k dielectric layers, the semiconductor chips having a satisfactory mechanical loadability.

Moreover, one or more embodiments provide a method for producing semiconductor chips having low-k dielectric layers in which fractures of the low-k dielectric layers during production and hence a high proportion of rejects are avoided.

A panel according to one embodiment composed of a composite plate composed of a plastic housing composition and semiconductor chips arranged in rows and columns on semiconductor device positions has at least one semiconductor chip having an active top side, a rear side and edge sides per semiconductor device position. The top side of the composite plate forms a coplanar area with the active top sides of the semiconductor chip. The plastic housing composition embeds the edge sides and the rear side of the semiconductor chip. The panel has a mono- or multilayer wiring structure with interconnects and dielectric layers composed of a low-k dielectric on the top side of the composite plate, wherein the active top side of each semiconductor chip is surrounded by a frame area composed of plastic housing composition. External contact areas are arranged on the frame area, the external contact areas being electrically connected to contact areas on the active top side of the semiconductor chip.

In accordance with one embodiment of the invention, fractures of the low-k dielectric layer when testing or making contact with the semiconductor chips can be attributed to the fact that the mechanical loading by a needle card for testing or by the contact-making, which loading acts directly from above on the contact areas and thus on the underlying porous low-k dielectric layer, is too high for the not very loadable low-k dielectric layer. A direct loading of the contact areas should therefore be avoided. Instead, external contact areas shifted away from the active chip area and from the low-k dielectric layer, the external contact areas being connected to the contact areas, should be testable and contact-connectable in a manner representative of the contact areas. By virtue of the arrangement of the external contact areas on the frame composed of plastic housing composition and surrounding the chip area, the external contact areas are loadable in contrast to the contact areas.

In one embodiment, the panel has the form and dimensions of a semiconductor wafer. It can therefore be processed further in a particularly simple manner with the infrastructure that exists anyway.

The external contact areas may be formed as test areas for functional tests. They may also firstly serve as test areas and subsequently be provided with surface-mountable external contacts such as solder balls or else with bonding wires.

The panel according to the invention has the advantage that the individual semiconductor chips are testable and, moreover, comparatively insensitive to mechanical loadings during the contact-connection of the contact areas during bonding or during the emplacement of components that are formed as flip-chip and are provided with solder balls. Although it is necessary to provide an additional frame area besides the actual chip area for fitting the loadable external contact areas, this additionally required area is comparatively small and, moreover, utilizes the area present anyway on the plastic housing.

A semiconductor device according to one or more embodiments has one or more semiconductor chips having an active top side, a rear side and edge sides. The semiconductor chips are embedded into a plastic housing composition. The active top side of the semiconductor chip or semiconductor chips forms a coplanar area with parts of the plastic housing composition and the edge sides are embedded into the plastic housing composition. A wiring structure with interconnects and dielectric layers composed of a low-k dielectric is arranged on the coplanar area. The active top side of each semiconductor chip is surrounded by a frame area composed of plastic housing composition and external contact areas are arranged on the frame area. The external contact areas are electrically connected to contact areas on the active top side of the semiconductor chip.

According to one embodiment, a method for producing semiconductor devices includes the following method. A semiconductor wafer having a multiplicity of semiconductor chip positions arranged in rows and columns is produced and is separated into a multiplicity of semiconductor chips having active top sides, edge sides and rear sides. A carrier is populated with semiconductor chips in semiconductor device positions, the semiconductor chips being fixed by their active top sides on the carrier in rows and columns. A plastic housing composition is applied to the carrier with embedding of the semiconductor chips by their edge sides into the plastic housing composition and with formation of a composite plate having a top side forming a coplanar area with the top sides of the semiconductor chips. The active top side of each semiconductor chip is surrounded by a frame area composed of plastic housing composition. After the curing of the plastic housing composition, the carrier is removed with formation of a self-supporting warpage-free panel.

A wiring structure having metallic interconnects and dielectric layers composed of a low-k dielectric can then be applied to the thus accessible top side of the composite plate and the active top sides of the semiconductor chips. Contact areas are applied to the active top side of the semiconductor chips and external contact areas are applied to the frame areas. The contact areas are electrically connected to respectively assigned external contact areas. Finally, the panel is separated into individual semiconductor devices.

In one embodiment, prior to the separation of the panel into individual semiconductor devices, a functional test of the semiconductor devices is performed via the external contact areas. Likewise prior to the separation of the panel, but expediently after the functional test, external contacts such as, for example, bonding wires or solder balls are fitted on the external contact areas.

The method according to one or more embodiments permits the production of semiconductor devices having a low-k dielectric which are testable and bondable without the production of an undesirably large number of rejects.

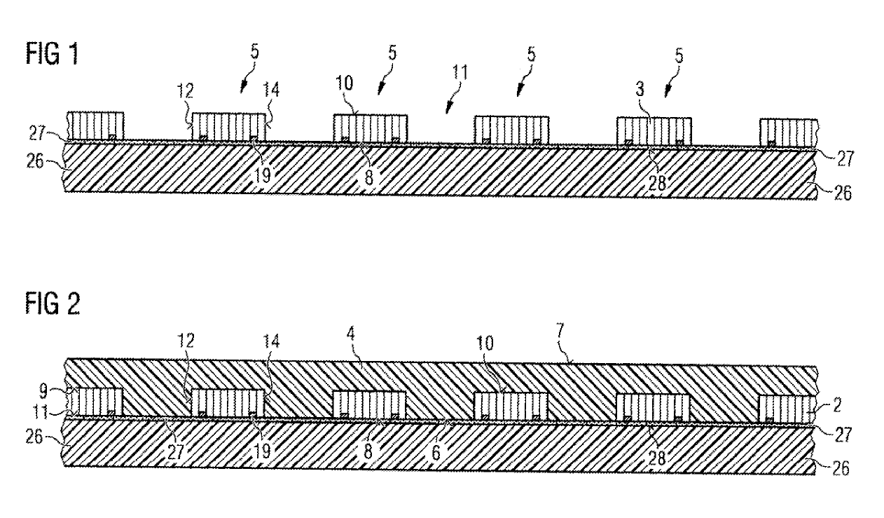

Individual fabrication stages of a semiconductor device are illustrated on the basis of schematic cross sections in FIGS. 1 to 7. A first process, in which a semiconductor wafer is first produced and then singulated into semiconductor chips, is not illustrated. FIG. 1 only illustrates the result of the subsequent process, in which the semiconductor chips 3, for example after previous functional testing, are placed onto a carrier 26 in semiconductor device positions 5.

In this embodiment, however, they are not arranged closely along side one another, rather interspaces 11 are left free between the individual semiconductor chips 3, which interspaces later, filled with plastic housing composition, become housing walls of semiconductor devices.

The semiconductor chips 3 are fixed by their active top sides 8 and the contact areas 19 situated thereon on the top side 28 of the carrier 26 with the aid of a double-sided adhesive film 27. In order to apply the semiconductor chips 3 in the semiconductor device positions 5, an automatic placement machine (not illustrated) is used which picks up the parts of a semiconductor wafer that have been separated into semiconductor chips 3 and exactly positions and fixes them on the top side 28 of the carrier 26 with the aid of the film 27.

On the top sides 8, the semiconductor chips 3 have above the semiconductor material a wiring structure (not illustrated) with metallic interconnects and layers composed of a low-k dielectric that are arranged on the semiconductor material and/or between the interconnects. Dielectrics having relative permittivities of less than 4 are appropriate as the low-k dielectric. The dielectric layer or the dielectric layers is or are porous and therefore not capable of withstanding high mechanical loading. Consequently, the contact areas 19 arranged on the dielectric layer should not be exposed to high loadings either. However, since there is no intention of dispensing with the low-k material on account of its contribution to avoiding parasitic inductances and capacitances, it is necessary to find a different way of relieving the load on the sensitive dielectric layer.

FIG. 2 illustrates a schematic cross section through the carrier 26 in accordance with FIG. 1 after the application of a plastic housing composition 4 by using compression moulding, injection moulding, laminating or dispensing technology into the interspaces 11 between the semiconductor chips 3 and on their rear sides 10. In this embodiment, the active top sides 8 of the semiconductor chips 3 with the plastic housing composition 4 form a coplanar area 9 of the composite plate 2.

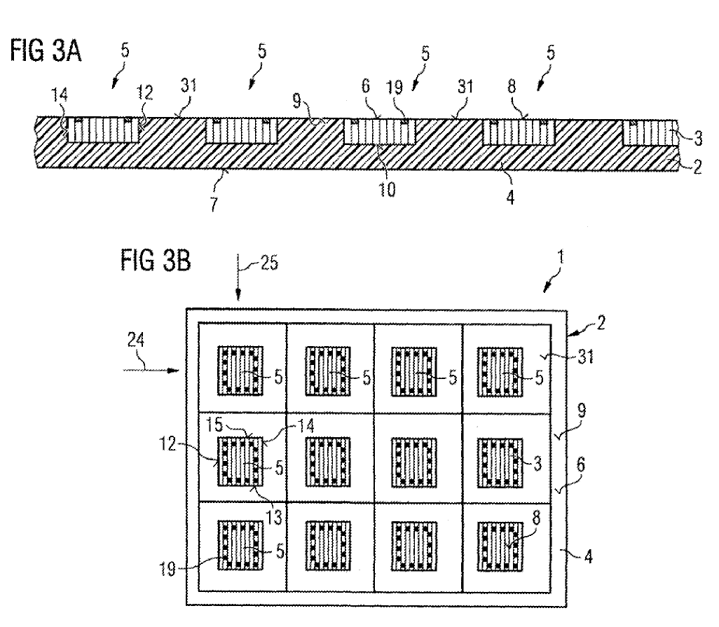

In a next process (not illustrated), the plastic housing composition 4 is cured. After curing, a stable, self-supporting composite plate 2 with semiconductor chips 3 embedded in the plastic housing composition 4 has formed and the carrier 26 is removed together with the film 27. The carrier 26 can be removed by heating the composite plate 2 and the carrier 26, in which case the double-sided adhesive film 27 loses its adhesion effect and the carrier 26 can be pulled off from the top side 6 of the composite plate 2 without considerable action of force on the composite plate 2. The result of this process is illustrated in FIG. 3a.

The semiconductor chips 3 of the composite plate 2 are at a distance from one another. The top side of each semiconductor chip 3 is surrounded by a frame area 31 composed of plastic housing composition. The frame areas 31 can be discerned particularly clearly in the plan view in FIG. 3b, where the illustration is not absolutely true to scale, rather the frame areas 31 typically, but not necessarily, turn out to be smaller in relation to the semiconductor chip 3 than illustrated.

The active top side 8 of the semiconductor chips 3 is freely accessible after the removal of the carrier, so that both the contact areas 19 and the remaining surface 8 of the semiconductor chips 3 and also the frame areas 31 are available for photolithographic methods.

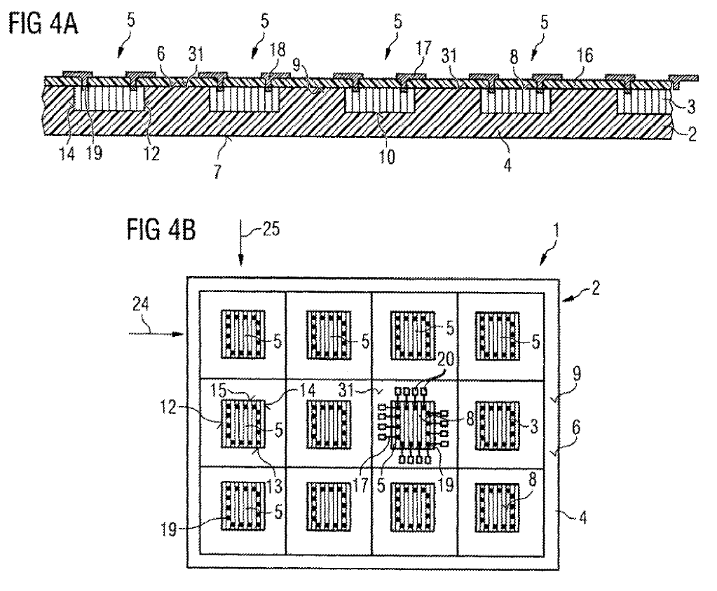

FIG. 4a illustrates a schematic cross section through the self-supporting composite plate 2 after the application of a wiring structure 17 to the coplanar top side 6 of the composite plate 2. The wiring structure 17 includes interconnects 18, which electrically interconnect external contact areas 20 on the frame area 31 to contact areas 19 on the active top sides 8 of the semiconductor chips 3. The external contact areas 20 simultaneously also form the external contact areas of the individual semiconductor devices in the individual semiconductor device positions 5. The wiring structure 17 may have a plurality of layers of interconnects 18.

By virtue of the external contact areas 20 being fitted on the frame areas 31, the mechanical loading when making contact with and/or testing the semiconductor chips 3 is as it were “diverted” from the fracture-sensitive, porous dielectric layer to the stable frame areas 31. FIG. 4b illustrates a plan view of the panel 1 with the semiconductor chips 3 embedded into the plastic housing composition 4. External contact areas 20 are arranged on the frame areas 31, the external contact areas being connected by interconnects 17 to the contact areas 19 on the active top side 8 of the semiconductor chips 3. In this case, typically each contact area 19 is assigned an external contact area 20, which can be tested and/or contact-connected in a manner representative of the contact area 19.

As illustrated in FIG. 5, a patterned soldering resist layer 21 can be applied to the wiring structure 17, which soldering resist layer covers the wiring structure 17 but leaves the external contact areas 20 free.

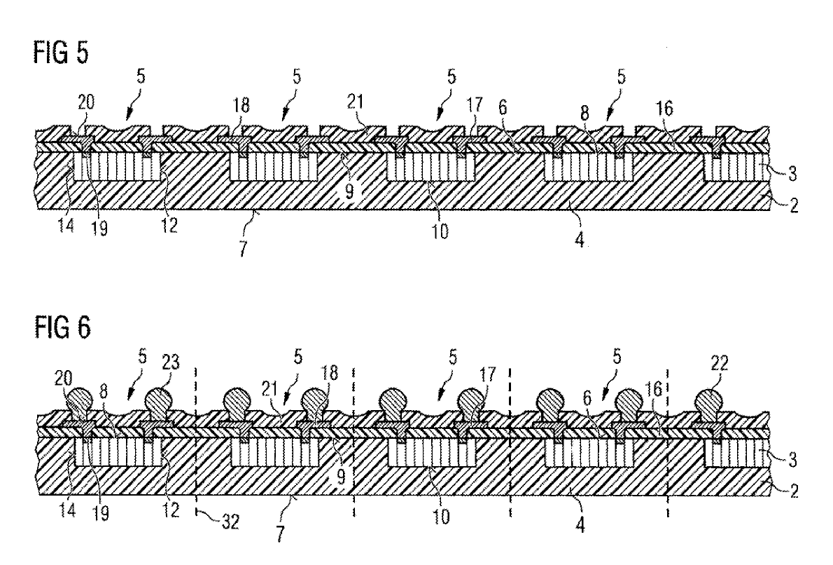

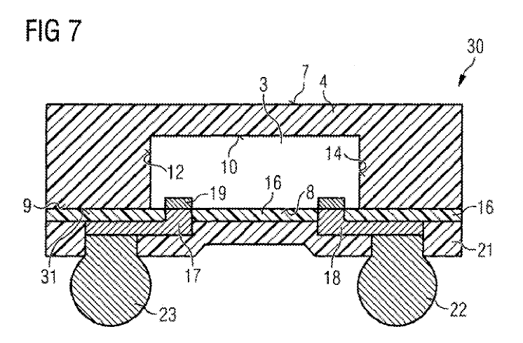

FIG. 6 illustrates a schematic cross section through a panel 1 after the application of external contacts 22 in the form of solder balls 23 to the external contact areas 20 on the top side 6 of the composite plate 2. The panel 1 is completed with this process and exhibits a complete semiconductor device according to the invention in each of the semiconductor device positions 5. By using a final process, the panel 1 is merely separated along the dashed lines 32 into semiconductor devices 30, one of which is illustrated in FIG. 7.

The semiconductor device 30 in accordance with FIG. 7 has only one semiconductor chip 3. It is possible, however, also to integrate a plurality of semiconductor chips or further discrete devices in a semiconductor device 30 according to the invention.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A panel comprising:
a composite; and
a wiring structure having interconnects, and dielectric layers comprised of a low-k dielectric.

2. The panel of claim 1, comprising:
the composite plate comprising a plastic housing and semiconductor chips.

3. The panel of claim 2, comprising:
where the dielectric layers are arranged on the semiconductor chips.

4. The panel of claim 1, comprising:
where the dielectric layers are arranged between the interconnects.

5. The panel of claim 1, comprising:
where the interconnects are metallic.

6. The panel of claim 1, comprising where the dielectric layers are arranged on a top side of the composite plate.

7. The panel of claim 1, comprising:
where the wiring structure is a multilayer wiring structure.

8. A panel comprising:
a composite plate composed of a plastic housing composition and semiconductor chips arranged in rows and columns on semiconductor device positions;
wherein at least one semiconductor chip having an active top side, a rear side and edge sides is provided per semiconductor device position;
wherein the composite plate has a top side forming a coplanar area with active top sides of the semiconductor chip;
wherein the plastic housing composition embeds the edge sides and the rear side of the semiconductor chip; and
wherein the panel has a mono- or multilayer wiring structure with interconnects and dielectric layers composed of a low-k dielectric on the top side of the composite plate.

9. The panel of claim 8, comprising:
where the active top side of each semiconductor chip is surrounded by a frame area composed of plastic housing composition; and
wherein external contact areas are arranged on the frame area, the external contact areas being electrically connected to assigned contact areas on the active top side of the semiconductor chip.

10. A panel of claim 8, comprising wherein the panel has the form and dimensions of a semiconductor wafer.

11. A panel of claim 8, comprising the external contact areas are formed as test areas for functional tests.

12. A panel of claim 8, comprising wherein the external contact areas have surface-mountable external contacts.

13. A panel of claim 12, comprising wherein the surface-mountable external contacts have solder balls.

14. A panel of claim 12, comprising wherein the surface-mountable external contacts have bonding wires.

15. A semiconductor device comprising:
a composite; and
a wiring structure having interconnects, and dielectric layers comprised of a low-k dielectric.

16. The device of claim 15, comprising:
the composite plate comprising a plastic housing and semiconductor chips.

17. The device of claim 16, comprising:
where the dielectric layers are arranged on the semiconductor chips.

18. The device of claim 15, comprising:
where the dielectric layers are arranged between the interconnects.

19. The device of claim 15, comprising:
where the interconnects are metallic.

20. The device of claim 15, comprising where the dielectric layers are arranged on a top side of the composite plate.

21. A semiconductor device comprising:
one or more semiconductor chips having an active top side, a rear side and edge sides, the semiconductor chips being embedded into a plastic housing composition, wherein the active top side of the semiconductor chip or semiconductor chips forms a coplanar area with parts of the plastic housing composition and the edge sides are embedded into the plastic housing composition; and
wherein a wiring structure with interconnects and dielectric layers composed of a low-k dielectric is arranged on the coplanar area.

22. The device of claim 21, further comprising:
wherein the active top side of each semiconductor chip is surrounded by a frame area composed of plastic housing composition, and wherein external contact areas are arranged on the frame area, the external contact areas being electrically connected to assigned contact areas on the active top side of the semiconductor chip.

23. The device of claim 22, comprising wherein the external contact areas are formed as test areas for functional tests.

24. The device of claim 22, comprising wherein the external contact areas have surface-mountable external contacts.

25. The device of claim 24, comprising wherein the surface-mountable external contacts have solder balls.

26. The device of claim 24, comprising wherein the surface-mountable external contacts have bonding wires.

27. A method of producing a semiconductor device comprising:
forming a composite plate having semiconductor chips; and
applying a wiring structure to a top side of the composite plate and an active top side of the composite plate and an active top side of the semiconductor chips, the wiring structure having dielectric layers composed of a low-k dielectric.

28. The method of claim 27, comprising:
producing a semiconductor wafer having a multiplicity of semiconductor chip positions arranged in rows and columns;
separating the semiconductor wafer into a multiplicity of semiconductor chips having active top sides, edge sides and rear sides;
populating a carrier with semiconductor chips in semiconductor device positions, the semiconductor chips being fixed by their active top sides on the carrier in rows and columns;
application of a plastic housing composition to the carrier with embedding of the semiconductor chips by their edge sides into the plastic housing composition and with formation of a composite plate having a top side forming a coplanar area with the top sides of the semiconductor chips, with the result that the active top side of each semiconductor chip is surrounded by a frame area composed of plastic housing composition; and
removing the carrier to form a panel.

29. The method of claim 28, comprising:
applying contact areas to the active top side of the semiconductor chips;
applying external contact areas to the frame areas;
electrical connecting contact areas to assigned external contact areas; and
separating the panel into individual semiconductor devices.

30. A method of claim 29, comprising where in separating the panel into individual semiconductor devices, a functional test of the semiconductor devices is performed via the external contact areas.

31. A method of claim 29, comprising wherein the separation of the panel into individual semiconductor devices, external contacts are fitted on the external contact areas.
